(19) United States
(12) Patent Application Publication
(10) Pub. No.: US 2012/0219917 A1
(43) Pub. Date: Aug. 30, 2012

(54) MULTIPLE PATTERNING CONSISTENCY PROCESSING

(75) Inventors: Patrick J. McGuinness, Austin, TX (US); Lionel J. Riviere Cazaux, Austin, TX (US)

(73) Assignee: FREESCALE SEMICONDUCTOR, INC., Austin, TX (US)

(21) Appl. No.: 13/036,604

(22) Filed: Feb. 28, 2011

(51) Int. Cl. G03F 7/20; G06F 17/50

(52) U.S. Cl. 430/312; 716/55

(57) ABSTRACT

Disclosed techniques for performing a multiple patterning consistency analysis of an integrated circuit design identify, in a standard cell array of the integrated circuit design, a set of standard cells for multiple patterning consistency analysis. The technique may also identify cell groups in the set where all of the cells in a cell group share a common multiple patterning orientation. The technique may identify unused elements in the standard cell array that are associated with or otherwise available for use in shifting at least some of the standard cells. The technique may shift the unused elements with respect to the cell groups, e.g., insert an unused element between a preferred orientation cell group and a non-preferred orientation cell group to shift the non-preferred group by one standard cell array element and thereby change the multiple patterning orientation of the cell group. The technique may shift the unused elements with the specific objective of reducing the prevalence of cell groups having the non-preferred multiple patterning orientation.

### FIELD OF THE DISCLOSURE

The present disclosure relates to integrated circuits and, more specifically, the design of integrated circuits fabricated in processes that employ a multiple patterning lithography process.

### BACKGROUND

In the field of semiconductor fabrication, the resolution of a photoresist pattern begins to blur at around 45 nm half-pitch. Multiple patterning photolithography processes were introduced in the semiconductor industry for the 32 nm half-pitch node and below, primarily using state-of-the-art 193 nm immersion lithography tools. Multiple patterning refers to a class of photolithography technologies developed to enhance feature density. The simplest case of multiple patterning is double patterning, where one or more aspects of a conventional photolithography process are duplicated to produce twice the expected number of features.

### BRIEF DESCRIPTION OF THE DRAWINGS

FIG. 1 depicts an embodiment of a first logic cell that exhibits a first double patterning orientation and a second logic cell that exhibits a second double patterning orientation;

FIG. 2 depicts a set of cells suitable for double patterning consistency analysis and refinement as described herein;

FIG. 3 is a block diagram depicting selected aspects of a method of analyzing the double patterning consistency of a set of cells in a standard cell based integrated circuit;

FIG. 4 is a block diagram depicting selected aspects of a method of fabricating an integrated circuit with a multiple patterning exposure process; and

FIG. 5 is a block diagram of selected elements of a data processing system suitable for performing an embodiment of a double patterning consistency process.

### DESCRIPTION OF THE EMBODIMENT(S)

Although there are several types of multiple patterning processes, multiple patterning analysis techniques disclosed herein are described in the context of double patterning process and, more specifically, a double exposure process that includes a sequence in which a photoresist layer is exposed a first time using a first photomask and then exposed a second time using a second photomask. It is to be understood that, although the multiple patterning embodiments described herein emphasize a double exposure process, other embodiments may employ three or more patterning steps and may employ a type of multiple patterning technique other than a multiple exposure technique.

The double exposure technique allows manufacturability of minimum pitch features in a layout that may contain a variety of features. Alternating phase-shift masks, for example, typically employ a double exposure approach. As long as double exposure can be used effectively and is kept within alignment tolerances, it is the preferred patterning approach since it does not require additional follow-up process steps.

Double patterning may result in a bimodal distribution of gate lengths and other transistor characteristics. Double-patterning in chip processing can induce distinct physical implementations of a defined transistor in a design, based on first or second pass of double-patterning, and timing differences may result due to double-patterning configuration differences. Techniques disclosed herein maximize or otherwise increase the number of cells aligned to a preferred double-patterning configuration or orientation. By improving the “double patterning orientation consistency” of the cells used for a standard cell instance, the disclosed subject matter offers better control over the cell instance timing and reduced variability of timing across different instances.

In one aspect, a disclosed method of designing an integrated circuit fabricated using a semiconductor fabrication process that employs a double patterning process that includes a first exposure and a second exposure includes identifying a set of cells in a standard cell portion of an integrated circuit design. The standard cell portion may include an array of standard cell elements including rows exhibiting an alternating pattern of two types of transistor gates. The types of transistor gates may referred to herein as alpha transistor gates, which are entirely or primarily defined by the first exposure, and beta transistor gates, which are entirely or primarily defined by the second exposure. Each cell in the set of cells may be associated with one of two double patterning orientations based on the types of transistor gates in the cell.

A cell, as the term is used herein, may refer to any set of elements in the standard cell array that combine to implement a defined function such as a logic function. The set of elements in a standard cell array may include an array of transistor gates arranged in rows and columns and exhibiting an alternating pattern of first transistor types and second transistor types.

The disclosed method may further include identifying cell groups within the set of cells. As used herein, the term cell group may refer to a group of cells sharing the same double patterning orientation. The types of cell groups may include preferred cell groups, which may include those cells having a first double patterning orientation, and non-preferred cell groups, which may include those cells having a second double patterning orientation. In some cases, a shell group may include available spaces located within the shell group while, in other cases, a shell group may refer to a group of like-oriented cells uninterrupted by any intervening spaces.

The method may include identifying, in the standard cell portion of the integrated circuit design, uncommitted transistor gates, also referred to herein as available spaces, that are associated with the identified set of cells, e.g., uncommitted transistor gates adjacent to or in close proximity to the identified set of cells. Based on the quantity of the available gates, at least some of the cell groups and some of the available gates may be shifted, shifted, or otherwise rearranged to achieve a specific objective. The objective may be (1) decreasing the quantity of cells having the non-preferred orientation, (2) decreasing the quantity of non-preferred cell groups, or (3) a combination of (1) and (2).

The set of cells that are identified might represent a cell island, which is used herein to refer to a set of adjacent and contiguously placed cells, e.g., a span of cells uninterrupted by available spaces or other array elements. In other cases, the identified standard cell portion may include some available spaces. In still other implementations, the identified portion may include an entire row of the transistor gates in the standard cell array. In still other embodiments, when available spaces outnumber the number of non preferred cells or cell groups, a set of identified cells may be categorized into “critical” cells and other cells. In these embodiments, the subsequent consistency optimization may prioritize the consistency of the critical cells. For example, if certain cells within an island or other identified set of cells are identified as timing-critical cells, the double patterning processing may be invoked to prioritize the consistency of the timing-critical cells. This prioritization might trump, for example, a factor such as the number of transistors in a cell or the number of cells in a cell group.

The double patterning orientation of a cell may be determined by a double patterning orientation of the leftmost, or first, transistor in the cell. The preferred double patterning orientation may be selected based on a performance characteristic of the two types of orientations. In other cases, however, the preferred double patterning orientation is defined to be the double patterning orientation of the first cell in the identified set of cells and the objective may be to maximize the double patterning uniformity or consistency of all cells or a selected set of cells. The term cell group may be used herein to refer to any subset of adjacent cells all having a common double patterning orientation or to any subset of cells and/or available spaces where all of the cells in the cell group have a common double patterning orientation.

When the quantity of available gates does not support sufficient cell shifting to eliminate all cells having the non-preferred orientation, i.e., achieve complete double patterning consistency, the method may include selectively shifting the cell groups based upon a weighting of the cell groups to ensure that prioritized cell groups have the preferred orientation. The weighting may, for example, indicate the number of cells in the respective cell group or, as another example, indicate how critical a cell is in terms of its timing window where, for example, the window of a cell characterized as having a critical timing window may be higher than the weighting of a cell characterized as not having a critical timing issue.

In another aspect, a disclosed tangible computer readable medium includes stored instructions (i.e., software), executable by a general purpose or special purpose processor, for performing a double patterning consistency analysis and/or refinement of an integrated circuit design. In this aspect, the software instructions may identify, in a standard cell array of the integrated circuit design, a set of standard cells for double patterning consistency analysis. The software instructions may also identify cell groups in the set, wherein all of the cells in a cell group share a common double patterning orientation. The software instructions may identify unused elements in the standard cell array that are associated with or otherwise available for use in shifting at least some of the standard cells. The software instructions may include instructions to shift the unused elements with respect to the cell groups, e.g., insert an unused element between a preferred orientation cell group and a non-preferred orientation cell group to shift the non-preferred group by one standard cell array element and thereby change the double patterning orientation of the non-preferred cell group. The software instructions may shift the unused elements with the objective of reducing the prevalence of cell groups having the non-preferred double patterning orientation.

In yet another aspect, a disclosed data processing system includes a general purpose or dedicated purpose processor having access to a computer readable storage medium. The storage medium includes software instructions, executable by the processor, to improve a double patterning consistency of standard cells an integrated circuit design. In this aspect of the disclosure, the software instructions may include instructions to identify a set of standard cells in a standard cell array of the integrated circuit design; identify, in the set of standard cells, cells groups including preferred cell groups having a preferred double patterning orientation and non-preferred cell groups having a non-preferred double patterning orientation; identify uncommitted standard cell elements associated with the set of standard cells; and shift, within the standard cell array, the uncommitted standard cell elements to the double patterning orientation of at least some of the cell groups.

In still another aspect, multiple patterning photolithography methods suitable for use in a semiconductor fabrication process for fabricating an integrated circuit are disclosed. These methods include a first photoresist exposure process, employing a first photomask, to define alpha type transistor gates within a standard cell portion of the integrated circuit and a second photoresist exposure process, employing a second photomask, to define beta type transistor gates within the standard cell portion. The beta type transistor gates alternate with the alpha type transistor gates within the standard cell portion. The first and second photomasks collectively define a set of cells within the standard cell portion and cell groups within the set of cells. Each cell in the set of cells is associated with one of a plurality of multiple patterning orientations determined by the types of transistor gates in the cell. A cell group includes a group of cells sharing a common multiple patterning orientation. The cell groups include first cell groups and second cell groups. Cells in the first cell groups have a first multiple patterning orientation while cells in the second cell groups have a second multiple patterning orientation. Cell groups and uncommitted transistor gates associated with the set of cells are laid out, positioned, or otherwise located to minimize a quantity of cells having the second multiple patterning orientation, to minimize a quantity of second cell groups, or both. The multiple patterning photolithography method may be implemented as a multiple exposure method that includes exposing a photoresist layer with the first photoresist exposure process and thereafter exposing the same photoresist layer with the second exposure process.

In the following description, details are set forth by way of example to facilitate discussion of the disclosed subject matter. It should be apparent to a person of ordinary skill in the field, however, that the disclosed embodiments are exemplary and not exhaustive of all possible embodiments. Throughout this disclosure, a hyphenated form of a reference numeral refers to a specific instance of an element and the un-hyphenated form of the reference numeral refers to the element generically or collectively. Thus, for example, widget 12-1 refers to an instance of a widget class, which may be referred to collectively as widgets 12 and any one of which may be referred to generically as a widget 12.

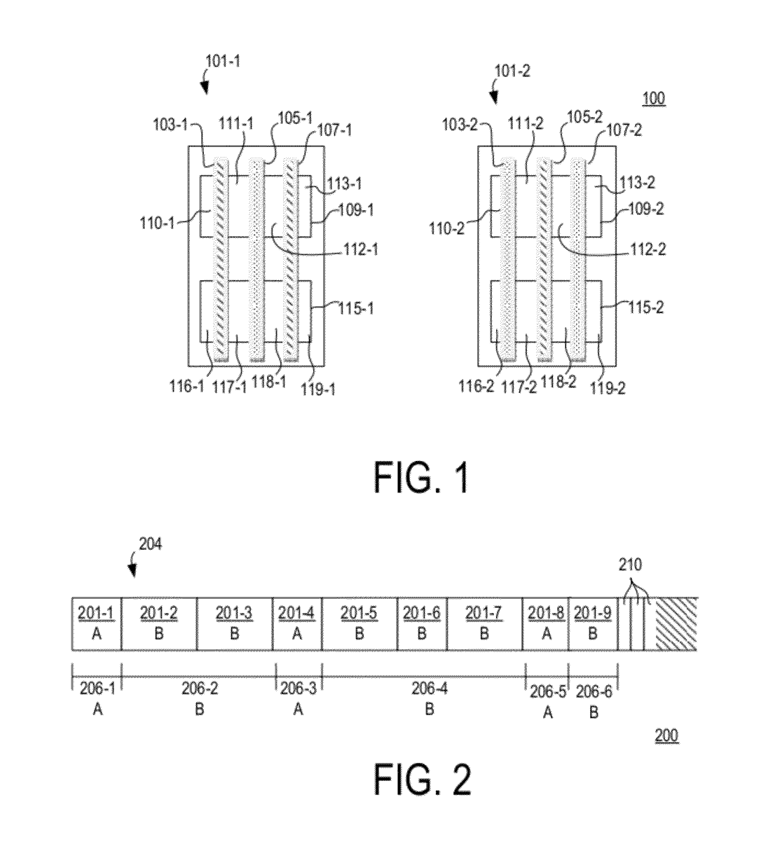

Referring now to the drawings, FIG. 1 is a top view depicting selected elements of a layout of a first cell 101-1 and a second cell 101-2, generically or collectively referred to herein as cell(s) 101. Cells 101 as depicted in FIG. 1 are multi-gate, field effect transistors (FETs), as will be familiar to those of skilled in the art of metal oxide semiconductor (MOS) integrated circuit design. Moreover, as discussed in greater detail below, cells 101 as shown in FIG. 1 may represent portions of an array of such cells, arranged in a uniform array, and referred to as standard cells. As used herein, the term “cell” may refer to any combination of transistors or transistor elements to implement a specified function, including a specified logic function.

Cells 101 as depicted in FIG. 1, for example, are suitable for implementing a 3-input logic function. Each cell 101 includes a first gate 103, a second gate 105, a third gate 107, each traversing a first active region 109 and a second active region 115 effectively dividing active region 109 into four distinct source/drain regions 110-113 and effectively dividing active region 115 into four distinct source/drain regions 116-119. Although not visible in the top view of FIG. 1, a thin dielectric film, referred to as the gate dielectric, separates transistor gates 103, 105, and 107 from the underlying active regions 109 and 115.

If source/drain regions 110-113 and 116-119 are n-type regions, those of ordinary skill will recognize that the application of a positive voltage in excess of the structure's threshold voltage to each of the transistor gates 103, 105, and 107, which function as the structure's inputs, will result in the formation of a conductive path between source/drain region 110 and source/drain region 113 as well as the formation of a conductive path between source/drain region 116 and source/drain region 119. Since one of the source drain regions 110 or 113 and one of the source/drain regions 116 or 119 is typically grounded, the other of the two source/drain regions, which functions as the structure's output, will be in a logical LO state (i.e., “pulled” LO) under these conditions. If there is insufficient voltage, i.e., a voltage below the structure's threshold voltage, applied at any of the transistor gates 103, 105, or 107, no conductive path between source/drain regions 110 and 113 or between source/drain regions 116 and 119 will exist and the ungrounded source/drain region, depending upon the design, may be pulled to a logical HI state. This functionality, in which a logic LO at any of the three inputs produces a logic HI at the output, is sometimes referred to as a 3-input NAND gate.

As indicated above, cells 101 may be a part of a larger array of standard cells in which the transistor gates are located on points of a uniformly spaced grid. As depicted in FIG. 1, for example, transistor gates 103-107 are arranged, in the x-direction, on points of a uniformly spaced grid. In some embodiments, the grid-like arrangement of transistor gates may extend in two directions such that, for example, the transistor gates are uniformly spaced in the x- and y-directions. Those of skill in the field of photolithographic processes used in the semiconductor industry will appreciate that arranging cell elements in a gridded pattern as depicted enables or facilitates the use of double exposure and other double patterning processes that result in the creation of two types of transistor and/or cell orientations. In addition, some implementations may employ one or more double-patterning lithography processes to achieve greater density of the transistor gates 103-107, i.e., reduce the spacing between adjacent gate structures, in the standard cells. Those of ordinary skill will recognize that, in a double patterning process, the performance characteristics of the devices may exhibit a bi-modal distribution, with the population defined by the first exposure exhibiting a first distribution and the population of transistors defined by the second exposure exhibiting a second distribution. Moreover, the distinctions between the two distributions of transistor devices may be sufficient to enable the designer or manufacturer recognize one of the two distributions as being preferred to the other in some cases. For example, the population of transistors defined by the first lithography process may exhibit greater speed and/or drive current than transistors defined by the second lithography process. In other cases, neither of the two distribution may be unilaterally preferable to the other, but it may, nevertheless, be preferable to maximize or increase the homogeneity of a group of cells by orienting as many of the cells as possible with a common double patterning orientation. This preference may be referred to herein as a preference for a consistent orientation.

In the standard cell configuration depicted in FIG. 1, the transistor gates defined by the first exposure are indicated with hash marking and may be referred to as alpha transistor gates while the transistor gates defined by the second exposure are indicated with shading and may be referred to herein as beta transistor gates. As depicted in FIG. 1, transistor gates 103-1, 107-1, and 105-2 are alpha transistor gates and transistor gates 105-1, 103-2, and 107-2 are beta transistor gates.

Comparing first cell 101-1 and second cell 101-2, the two cells exhibit different orientations. First cell 101-1 is oriented wherein two of its transistor gates (103-1 and 107-1), including its first or left-most transistor gate 103-1, are alpha transistor gates while second cell 101-2 is oriented wherein two of its transistor gates (103-2 and 107-2), including its first or left-most transistor gate 103-2 are beta transistor gates. Moreover, although the cells depicted in FIG. 1 are 3-input NAND gates, a standard cell array can be configured to accommodate additional types of logic gates and/or logic gates having more or fewer inputs. In the case of more or fewer inputs, cells may be referred to herein as being alpha or beta oriented based on the orientation of the cell's first or left-most transistor (as viewed from a predefined perspective such as the perspective represented in FIG. 1). Moreover although the present disclosure is illustrated and explained for an implementation in which double exposure is used, other embodiments of a multiple patterning process may employ three or more exposure steps and, in these cases, aspects of the double patterning consistency optimization disclosed herein may be employed or extended to accommodate, for example, a design in which the standard cells may exhibit one of three or more multiple patterning orientations.

Returning to the case of double patterning represented by cells 101, a standard cell array may include an array of alpha and beta transistor gates arranged in an alternating pattern as is the case for cells 101. In this configuration, those of skill may appreciate that shifting a cell having an alpha orientation by one transistor gate will transform the orientation of the cell to a beta orientation while shifting a beta oriented cell by a single transistor gate will transform the configuration to an alpha configuration, i.e., the orientation of the cell's first transistor gate will change. Disclosed embodiments may maximize or improve the configuration of an integrated circuit by rearranging cells in a standard cell array to reduce or minimize the number of non-preferred cells or to increase or maximize the amount of double patterning orientation consistency or double patterning orientation uniformity.

Referring now to FIG. 2, a selected portion 200 of an embodiment of a standard-cell-based integrated circuit is depicted. As depicted in FIG. 2, the selected portion 200 includes a standard cell “island” 204 that includes a set of standard cells 201-1 through 201-9 where there are no spare or otherwise unused elements of the standard cell array, e.g., no unused transistor gates, within island 204. Each standard cell 201 is associated with or characterized by a double patterning orientation, which is indicated FIG. 2 by the letter “A” for alpha oriented cells and the letter “B” for beta oriented cells. Island 204 as depicted in FIG. 2 emphasizes that the double patterning orientation of a cell is a placement-dependent characteristic. For example, assuming that the double patterning orientation of a cell 201 is determined by the double patterning exposure that defines the first transistor gate in the cell and that the standard cell array includes an alternating pattern of alpha and beta transistor gates, the double patterning orientation of any cell 201 can be changed by shifting the cell by one array element, i.e., one transistor gate.

FIG. 2 also depicts cell groups 206-1 through 206-5 within island 204. A cell group 206 represents a set of one or more cells 201 where each of the cells 201 in the group 206 have the same double patterning orientation. Thus, for example, island 204 as depicted in FIG. 2, includes five cell groups, 206-1 through 206-5 where cell group 206-1 includes cell 201-1 only, cell group 206-2 include cells 101-2 and 201-3, both being beta oriented cells, cell group 206-3 includes cell 201-4 only, cell group 204-4 include cells 201-5, 201-6, and 201-7, and group 206-5 includes cell 201-8 only. The double patterning orientation of a cell group 206 is determined by the double patterning orientation of the cells 201 in the group. Thus, cell group 206-1 has an alpha double patterning orientation, cell group 206-2 has a beta double patterning orientation, and so forth. FIG. 2 thus emphasizes that the double patterning orientation of cell groups 206 form an alternate sequence of alpha and beta orientations (ABAB . . . ). Depending upon the implementation, a cell group 206 may include available spaces as well as like-oriented cells 201.

In some embodiments, a technique for improving orientation uniformity or orientation consistency includes assigning a weighting to each group 206 within an island 204 of cells 201. In some embodiments, the weighting assigned to a group 206 is determined by the number of cells 201 within the group 206. Referring to FIG. 2, for example, an exemplary weighting for the groups 206 would assign a weighting of 1 to group 206-1 because it has a single cell 201-1, a weighting of 2 to group 206-2, because it includes two cells 201-2 and 201-3, a weighting of 1 to group 206-3 a weighting of 3 to group 206-4 because it includes cells 201-5, 201-6, and 201-7 and so forth. The weightings assigned to groups 206 may be used to prioritize or otherwise selectively determine which cells 201 might be shifted to improve double patterning orientation consistency when the number of spare transistor gates available is not sufficient to eliminate completely all of the orientation inconsistency in an island. As suggested previously, weightings may also be used to identify cells known or believed to be within or otherwise part of a critical timing parameter.

FIG. 2 depicts available, unused, or uncommitted transistor gates 210, also referred to herein as available spaces or available spaces, adjacent to island 204. As depicted in FIG. 2, there are 3 such available transistor gates 210, which can be rearranged with the elements of island 204 to alter the double patterning orientation of individual cells 201 and/or entire cell groups 206. If more than 3 spare transistor gates 210 were required to remove all of the orientation inconsistency in island 204, a double patterning orientation consistency improvement might still be made, albeit resulting in a less than completely consistent double patterning orientation, and such an improvement might be guided by the weighting of groups within the island.

Some embodiments of double patterning orientation consistency processing as disclosed herein may be implemented in the form of computer software, i.e., computer instructions, executable by a general purpose processor, stored or embedded in a semiconductor memory or other form of tangible computer readable storage medium.

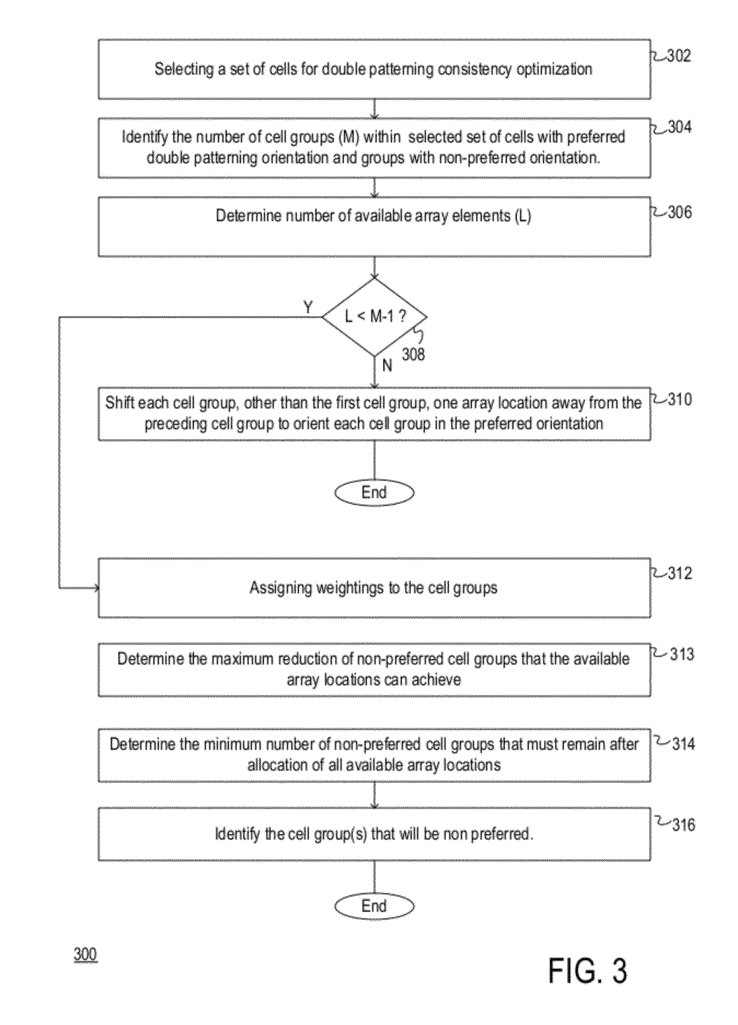

Referring now to FIG. 3, a flow diagram illustrates an embodiment of a method 300 of improving orientation consistency in an integrated circuit manufactured with a fabrication process that employs a double patterning or other multiple patterning process. As suggested above, method 300 may be implemented as a set of instructions stored or otherwise embedded in a tangible computer readable memory or other type of storage medium. In the depicted embodiment, method 300 includes selecting (block 302) or otherwise identifying a set of cells on which to perform a double patterning orientation consistency analysis and/or refinement. Those of skill will appreciate that, in at least some implementations, the process is performed prior to committing the design of the applicable integrated circuit to a mask set. In some implementations, the design process for a standard-cell-based integrated circuit may include a cell placement verification and refinements step, sometimes referred to as a “placement and legalization” step, in which the placement of individual cells of a design within an array of standard cells are verified, checked against a set of design and/or process rules, and refined as applicable. The double patterning consistency analysis/refinement procedures described herein may be implemented as a distinct or integrated aspect of the placement and legalization process.

Returning to FIG. 3, the depicted embodiment of method 300 includes identifying the number of cell groups (M) within the set of cells that has been selected (in block 302) for double patterning consistency optimization. As discussed above with respect to the example presented in FIG. 2, a cell group refers to a set of cells that share the same double patterning orientation. Because all cells in a cell group share the same double patterning orientation, a cell group is a useful subset from a double patterning orientation perspective because the double patterning orientation of all of the cells in the group are similarly affected when the group is shifted from placement to a new placement. If, for example, all of the cells in a cell group are alpha cells and all of the cells are shifted by one array location, e.g., one transistor gate, then the double patterning orientation of all of the cells would change from alpha to beta. As indicated previously, the cell groups exhibit an alternating double patterning orientation pattern, i.e., the double patterning orientation of a cell group N will differ from the double patterning orientation of cell groups N−1 and N+1.

In the embodiment depicted in FIG. 3, block 304 may also include specifically identifying the number of groups that have a non-preferred orientation. While the non-preferred orientation may be an orientation that exhibits certain performance characteristics in some cases, the non-preferred orientation may simply refer to the orientation of a cell or cell group in a specified position of the island. For example, when the objective of double patterning consistency optimization is too maximize or increase the number of cells that share a common double patterning orientation, it may be desirable to designate the double patterning orientation of the first cell group as the preferred double patterning orientation and to designate the double patterning orientation of the second cell group as the non-preferred double patterning orientation.

Regardless of how the preferred double patterning orientation is determined, the depicted embodiment of block 304 includes determining the number of non-preferred cell groups. The number of non-preferred cell groups determines a maximum value on the number of available spaces that would be needed to achieve complete double patterning orientation consistency.

Thus, the depicted embodiment of FIG. 3 includes determining (block 306) the number of available spaces (L). Referring back to FIG. 2, available spaces may refer to transistor gate structures 210 that are not assigned to a functional cell. If there are sufficient available spaces to eliminate all orientation inconsistency within an island, method 300 includes shifting each of the M−1 groups (not including the first group), by one array location, i.e., inserting a spare location between each adjacent pair of cell groups. Thus, for example, if an island of cells includes 6 cell groups (including 3 preferred cell groups and 3 non-preferred cell groups), a minimum of 5 available spaces are needed to eliminate all orientation inconsistency. More generally, when there are M cell groups, a minimum of M−1 available spaces are needed to achieve complete double patterning orientation consistency.

If the number of available spaces L is not less than M−1, as determined in block 308, method 300 branches to block 310, where a “space” is “inserted” between each pair of cell groups by shifting the available spaces to achieve complete double patterning orientation consistency. When L is insufficient to eliminate all double patterning orientation inconsistency, a methodology for prioritizing or utilizing the available array locations must be implemented. Various utilization methodologies may be employed. In a simplistic methodology, the spare array locations may simply be inserted based on the position of a cell group within the island or other identified set of cells. For example, the first available space may be used to change the double patterning orientation of the right-most non-preferred group while subsequent available spaces would be used to change the double patterning orientation status of the next non-preferred group. While such a methodology is feasible, the depicted embodiment of method 300 depicted employs a utilization methodology in blocks 312-316 that allocates scarce available spaces to the cell groups in a manner that minimizes the number of non-preferred cells.

As depicted in FIG. 3, a weighting is assigned (block 312) to each of the cell groups in the island under consideration. As discussed previously, the weighting employed may reflect or correlate to a definable characteristic of the cell group such as the “critical-ness” of the timing of the cell group or, as another example, the number of cells that the cell group contains. For example, a cell group that contains 3 cells might be assigned a weighting of 3 while a cell group that contains just 2 cells might be assigned a weighting of 2. Similarly, in an embodiment that weights cell groups based on a critical timing basis, may weight non-critical cells as having zero weight, i.e., cells or cell groups that would rarely, if ever, be relocated even in the presence of sufficient spare elements.

The depicted embodiment of method 300 then determines the minimum number of non-preferred cell groups that would remain after an optimal allocation of all available spaces. This number is equal to the number of non-preferred cell groups in the island as originally laid out minus the maximum reduction in the number of non-preferred cell groups that can be achieving with the available spaces. If, for example, there are 5 non-preferred cell groups in an island and the available spaces can be used to reduce the number of non-preferred cell groups by, at most, 3, then at least 2 non-preferred cell groups will remain after double patterning consistency optimization. This number is useful in a double patterning optimization process that attempts to select which cell groups will have a non-preferred orientation after the double patterning optimization is complete. Using a simple example to illustrate, if it is determined that, after double patterning optimization, a cell island will include at least 1 cell group having a non-preferred orientation, a double patterning optimization process as described herein might attempt to insure that the cell group having the non-preferred orientation is the cell group with the smallest weighting, e.g., the cell group having the fewest cells.

In method 300, the maximum reduction in the number of non-preferred cell groups that can be achieved using the available spaces is determined in block 313. This number is a function of the number of available spaces and whether the island has an even or odd number of cell groups. In the case of an odd number of cell groups (e.g., an island having an ABABA pattern of cell groups where A represents an alpha or preferred cell group and B represents a beta or non-preferred cell group), the maximum by which the number of non-preferred cell groups can be reduced is equal to Mod [L/2], where L is still the number of available spaces and Mod [X] is the modulo function, which returns the integer portion of a real value, e.g., Mod [1.5]=1. In the case of an island having an even number of cell groups, e.g., ABABAB, the minimum number by which the number of non-preferred cell groups can be reduced is equal to Mod [(L+1)/2].

Thus, as an example, if there are 3 array elements available (L=3) to perform double pattern orientation refinement on an island of cells having 8 cell groups (A₁B₂A₃B₄A₅B₆A₇B₈xxx where the subscript identifies the corresponding group, “A” and “B” indicate preferred or non-preferred orientation, and “x” indicates an available space), the 3 array locations can be used to reduce the number of non-preferred cell groups by Mod [(3+1)/2] or 2 such that, after double patterning optimization, there will be 6 groups having a preferred orientation and 2 groups having a non-preferred orientation (e.g., A₁B₂A₃B₄A₅xA₆xA₇xA₈, where lower case “x” represents an insertion of one of the available spaces. In this example, cell group 6 has been moved by one array location to change from a B group to an A group, cell group 7 has been moved by two array locations and, therefore, remains as an A group, and cell group 8 has been moved by three array locations to change from a B group to an A group.

Block 314 of method 300 as depicted in FIG. 3 determines the minimum number of non-preferred cell groups that must remain after fully allocating all of the available spaces by computing the difference between the number of non-preferred cells in the original configuration and the maximum achievable reduction in the number of non-preferred groups determined in block 313. For example, in the case of a cell island having 8 cell groups, which would be 4 preferred cell groups A and 4 non-preferred cell groups B arranged in an ABABABAB pattern, where there are 3 array locations available for cell group shifting, the minimum number of non-preferred cell groups that remain after allocating the 3 available spaces would be 4−Mod [(3+1)/2] or 2.

After determining how many non-preferred cell groups will remain in block 314, the depicted embodiment of method 300 then determines (in block 316) which of the cell groups will have the non-preferred orientation after double patterning optimization. Although various algorithms may be employed to select the non-preferred groups, one such algorithm selects the non-preferred cell groups, i.e., selects the locations into which the available spaces will be inserted, based on the weightings of the cell groups. For example, an algorithm may identify each of the finite set of cell placements, achievable using the available spaces, that results in the minimum number of non-preferred cell groups. The algorithm would then determine the number of non-preferred cells in the group and select the cell placement that results in the smallest number of non-preferred cells. For example, if the algorithm determines that there are 3 possible cell placements that achieve the minimum number of non-preferred cell groups, the algorithm would determine how many cells are contained in the 3 non-preferred groups and selected the placement having the smallest number of non-preferred cells. If the number of non-preferred cells is the same for two or more of the possible placements, prioritization of these candidates can be done, for example, based on an arbitrary factor, e.g., choose the configuration in which the left-most non-preferred group is furthest to the right, or based on some other factor capable of distinguishing the two or more candidates.

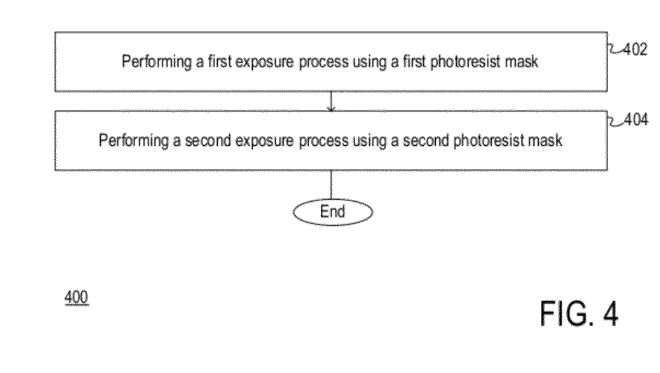

Referring now to FIG. 4, a block diagram depicting selected elements of a semiconductor fabrication process 400 is presented. Semiconductor fabrication process 400 employs at least one multiple patterning photolithography process and is suitable for fabricating integrated circuits including integrated circuits having features characterized by a half pitch of less than 45 nm. In some embodiments, the integrated circuits may have features characterized by a half pitch of approximately 32 nm or less. In the embodiment of method 400 depicted in FIG. 4, method 400 includes a first exposure process 402 employing a first photoresist mask. The first photoresist mask defines alpha type transistor gates. A second exposure process 404 employs a second photoresist mask. The second photoresist mask defines beta type transistors. Method 400 may be implemented as a multiple exposure method in which first exposure 402 and second exposure 404 are performed on the same layer of photoresist.

Consistent with the multiple patterning consistency techniques described above with respect to FIG. 1, FIG. 2, and FIG. 3, the first and second photoresist masks employed by method 400 are designed to collectively define a set of cells within a standard cell portion of the integrated circuit and to define cell groups within the set of cells. Each cell in the set of cells is associated with one of a plurality of multiple patterning orientations determined by the types of transistor gates in the cell. As described above, a cell group includes a group of cells sharing a common multiple patterning orientation. The cell groups include first cell groups and second cell groups. Cells in the first cell groups have a first double patterning orientation while cells in the second cell groups have a second double patterning orientation. Cell groups and uncommitted transistor gates associated with the set of cells are laid out, positioned, or otherwise located based on the quantity of resulting cells having the second multiple patterning orientation, the quantity of resulting second cell groups, or both. For example, the cell groups and uncommitted transistor gates may be positioned to minimize the cells having the second orientation, to minimize the number of second cell groups, or both.

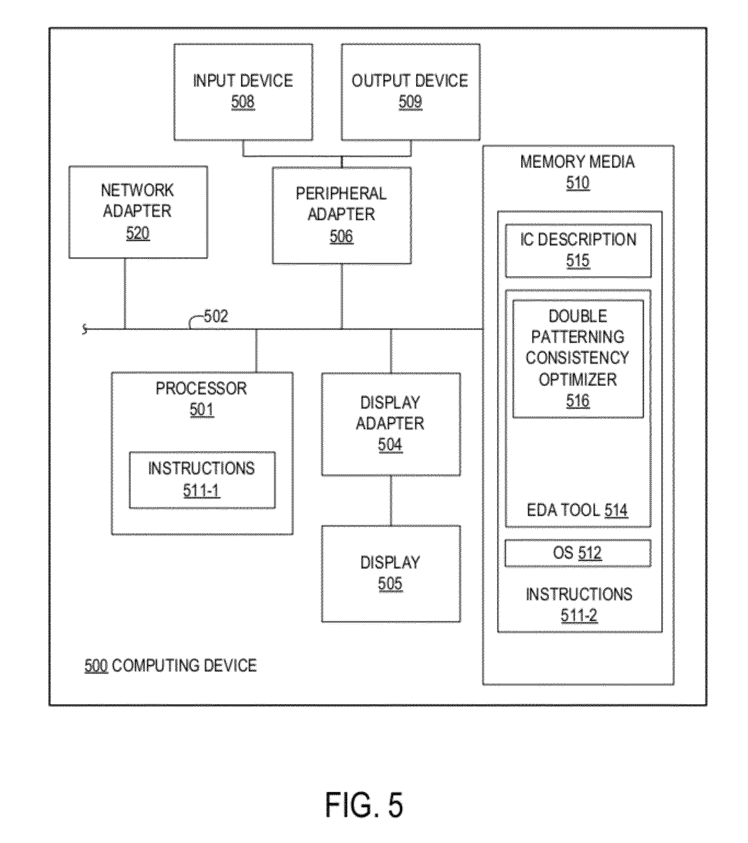

Referring now to FIG. 5, a block diagram illustrating selected elements of an embodiment of a data processing system 500 for performing double patterning consistency optimization as disclosed herein. In the embodiment depicted in FIG. 5, device 500 includes processor 501 coupled via shared bus 502 to storage media collectively identified as memory media 510. Device 500 may be configured to perform any of the methods disclosed herein

Device 500, as depicted in FIG. 5, further includes network adapter 520 that interfaces device 500 to a network (not shown in FIG. 4). In embodiments suitable for use in database systems, device 500, as depicted in FIG. 5, may include peripheral adapter 506, which provides connectivity for the use of input device 508 and output device 509. Input device 508 may represent a device for user input, such as a keyboard or a mouse, or even a video camera. Output device 509 may represent a device for providing signals or indications to a user, such as loudspeakers for generating audio signals.

Device 500 is shown in FIG. 5 including display adapter 504 and further includes a display device or, more simply, a display 505. Display adapter 504 may interface shared bus 502, or another bus, with an output port for one or more displays, such as display 505. Display 505 may be implemented as a liquid crystal display screen, a computer monitor, a television or the like. Display 505 may comply with a display standard for the corresponding type of display. Standards for computer monitors include analog standards such as video graphics array (VGA), extended graphics array (XGA), etc., or digital standards such as digital visual interface (DVI), high definition multimedia interface (HDMI), among others. A television display may comply with standards such as NTSC (National Television System Committee), PAL (Phase Alternating Line), or another suitable standard. Display 505 may include an output device 509, such as one or more integrated speakers to play audio content, or may include an input device 508, such as a microphone or video camera.

Memory media 510 encompasses persistent and volatile media, fixed and removable media, and magnetic and semiconductor media. Memory media 510 is operable to store instructions, data, or both. Memory media 510 as shown includes sets or sequences of instructions 511-2, namely, an operating system 512 and an application or module identified as double patterning consistency optimizer 516 which is depicted as an integrated aspect of an EDA tool 514 although optimizer 516 might also be implemented as a stand alone application that operates on a data structure, such as the data structure identified as IC design description 515, generated by an EDA tool. IC design description 515 may include a register level description, a gate level description, a layout description, or any combination thereof of an integrated circuit design. Operating system 512 may be a UNIX or UNIX-like operating system, a Windows® family operating system, or another suitable operating system. Instructions 511 may also reside, completely or at least partially, within processor 501 during execution thereof. It is further noted that processor 501 may be configured to receive instructions 511-1 from instructions 511-2 via shared bus 502. In some embodiments, memory media 510 is configured to store and provide executable instructions for double patterning consistency process as described above with respect to FIG. 3. For example, double patterning consistency optimizer 514 may be configured to execute method 300 of FIG. 3.

To the maximum extent allowed by law, the scope of the present disclosure is to be determined by the broadest permissible interpretation of the following claims and their equivalents, and shall not be restricted or limited to the specific embodiments described in the foregoing detailed description.

What is claimed is:

1. A method of designing an integrated circuit fabricated using a semiconductor fabrication process that employs a double patterning process, the double patterning process employing a first exposure and a second exposure, the method comprising:
identifying a set of cells in a standard cell portion of an integrated circuit design, wherein the standard cell portion includes an alternating pattern of two types of transistor gates including alpha transistor gates, defined by the first exposure, and beta transistor gates, defined by the second exposure, and wherein a cell in the set of cells is associated with one of two double patterning orientations determined by the types of transistor gates in the cell;
identifying cell groups within the set of cells, wherein a cell group comprises a group of cells sharing the same double patterning orientation, and wherein the cell groups include preferred cell groups comprising cells having a first double patterning orientation and non-preferred cell groups comprising cell having a second double patterning orientation;
identifying, in the standard cell portion, available transistor gates associated with the set of cells; and
based on a quantity of the available gates, selectively shifting at least some of the cell groups and some of the available gates to achieve an objective selected from: decreasing a quantity of cells having the non-preferred orientation and decreasing a quantity of the non-preferred cell groups.

2. The method of claim 1, wherein identifying the set of cell comprises identifying a cell island, wherein the cell island comprises a contiguous set of cells.

3. The method of claim 1, wherein the standard cell portion comprises an array of transistor gates and wherein identifying the set of cells comprises identifying an entire row of the array.

4. The method of claim 1, wherein the double patterning orientation of the cell is determined by a type of a first transistor in the cell.

5. The method of claim 1, wherein a double patterning orientation of a first cell in the set of cells is defined to be the preferred double patterning orientation.

6. The method of claim 1, wherein the cell group comprises a set of adjacent cells that share a common double patterning orientation.

7. The method of claim 1, wherein, when the quantity of available gates is insufficient to eliminate all cells having the non-preferred orientation, selectively shifting the cell groups includes shifting cell groups selected based upon a weighting of the cell groups, wherein the weighting is indicative of the number of cells in the cell group.

8. A tangible computer readable medium including stored instructions, executable by a processor, for performing a double patterning consistency analysis of an integrated circuit design, the instructions comprising instructions to:
identify, in a standard cell array of the integrated circuit design, a set of standard cells for double patterning consistency analysis;
identify cell groups in the set, wherein standard cells in a cell group share a common double patterning orientation;
identify unused elements in the standard cell array associated with the set of standard cells; and
shift the unused elements to change the double patterning orientation of selected cell groups.

9. The computer readable medium of claim 8, wherein the instructions to identify the set of standard cells comprises instructions to identify a cell island, wherein a cell island comprises a contiguous set of cells.

10. The computer readable medium of claim 8, wherein the instructions to identify the set of standard cells comprises instructions to identify an entire row of the array.

11. The computer readable medium of claim 8, wherein the double patterning orientation of a cell is determined by an exposure type of a first transistor in the cell, wherein the exposure type is selected from a first exposure type indicating a transistor defined by a first exposure of a double patterning process and a second exposure type indicating a transistor defined by a second exposure of the double patterning process.

12. The computer readable medium of claim 8, wherein the double patterning orientation of a cell is selected from a group consisting of a preferred double patterning orientation and a non-preferred double patterning orientation and wherein the preferred double patterning orientation is defined based on double patterning orientation of a first cell in the cell group and further wherein the instructions to shift the unused elements to reduce the prevalence of cell groups having the non-preferred double patterning orientation.

13. The computer readable medium of claim 8, wherein a cell group comprises all adjacent cells of a common double patterning orientation.

14. The computer readable medium of claim 8, wherein, when the standard cell array includes an array of transistor gates and wherein the unused elements comprise unused transistor gates.

15. A multiple patterning photolithography method for use in a semiconductor fabrication process for fabricating an integrated circuit, the multiple patterning photolithography method comprising:
a first photoresist exposure process employing a first photomask to define alpha type transistor gates within a standard cell portion of the integrated circuit; and
a second photoresist exposure process employing a second photomask to define beta type transistor gates within the standard cell portion, wherein the beta type transistor gates alternate with the alpha type transistor gates within the standard cell portion;
wherein the first photomask and the second photomask collectively define a set of cells within the standard cell portion and cell groups within the set of cells;
wherein a cell in the set of cells is associated with one of a plurality of multiple patterning orientations determined by the types of transistor gates in the cell;
wherein a cell group includes a group of cells sharing a common multiple patterning orientation, and wherein the cell groups include first cell groups comprising cells having a first multiple patterning orientation and second cell groups comprising cells having a second multiple patterning orientation; and
wherein cell groups and uncommitted transistor gates associated with the set of cells are positioned to achieve an objective selected from minimizing a quantity of cells having the second multiple patterning orientation and minimizing a quantity of second cell groups.

16. The multiple patterning photolithography method of claim 15, wherein the method includes exposing a photoresist layer with the first photoresist exposure process and thereafter exposing the photoresist layer with the second exposure process.

17. The multiple patterning photolithography method of claim 15, wherein a multiple patterning orientation of a first cell in the set of cells is defined as the first multiple patterning orientation.

18. The multiple patterning photolithography method of claim 15, wherein the cell group comprises a set of adjacent cells that share a common multiple patterning orientation.

19. The multiple patterning photolithography method of claim 15, wherein the set of cells comprises a cell island, wherein the cell island consists of a contiguous set of cells.

20. The multiple patterning photolithography method of claim 15, wherein the standard cell portion comprises an array of transistor gates and wherein the set of cells comprises an entire row of the array.
